(19) United States
(12) Patent Application Publication
(10) Pub. No.: US 2012/0228124 A1
(43) Pub. Date: Sep. 13, 2012

(54) METHOD OF CREATING PVD LAYERS USING A CYLINDRICAL ROTATING CATHODE AND APPARATUS FOR CARRYING OUT THIS METHOD

(76) Inventors: Stan Veprek, Eching/Dietersheim (DE); Mojmir Jilek, Sumperk (CZ); Ondrej Zindulka, Rapotin (CZ)

(21) Appl. No.: 13/510,377

(22) PCT Filed: Nov. 22, 2010
(86) PCT No.: PCT/CZ2010/000117

§ 371 Date: May 17, 2012

(30) Foreign Application Priority Data
Nov. 23, 2009 (CZ) PV-2009-784

(51) Int. Cl. C23C 14/35

(52) U.S. Cl. 204/192.12

(57) ABSTRACT

A method of depositing wear resistant layers, using PVD method, where the depositing is carried out from at least two working deposition sources, simultaneously, where at least one of said sources is a cylindrical rotating cathode working in an unbalanced magnetron regime and simultaneously, at least one of said sources is a cathode, working in low-voltage arc-discharge regime. Further, the invention is related to the apparatus for carrying out said method, the apparatus consisting of vacuum deposition chamber, in which there are at least two deposition sources with their relevant gas inputs of process gases and their shields, and in which at least one substrate on rotating support is placed, and where the most substantive is that at least one of said sources is a cylindrical rotating cathode working in an unbalanced magnetron regime, and, simultaneously, at least one of said sources is a cathode, working in low-voltage arc-discharge regime.

### FIELD OF THE INVENTION

The invention is related to the method of application, deposition, or coating of material by abrasion resistant layers, using a method of PVD, where the coating is performed by a combination of magnetron sputtering and arc sputtering. The invention is related to an apparatus for carrying out this method, too.

### BACKGROUND OF THE INVENTION

There are known plurality of variations of methods, and apparatus, too, for preparation of PVD layers. As the closest state-of-the-art in relation to the present invention it seems to be following publications.

In EP 1538496 methods using rotation cylindrical targets for preparation of PVD layers by low-voltage arc are described, where not only more even deposited layer and more effective target material yield is achieved but using of stronger magnetic field is possible, too, what reduces a dimension and a number of macroparticles in the deposited layer.

WO 2007/044344 discloses methods using cylindrical targets for a magnetron sputtering, where an internal cavity for placing a magnetic field is used. The magnetic field creates one or more closed ducts of this magnetic field on the surface of the target, which ducts are oriented parallel to the axis of the target and so the layer can be more even and a material of the target is worked out more effectively.

WO 2007/044344 discloses methods of using cylindrical rotational magnetron targets for producing PVD layers, too, where thanks to a rotation of the target the life of this target is longer and the efficiency of material yield of this target is higher.

Further, methods of creating more efficient design of cylindrical magnetrons are known, where a masking of targets ends is provided in accordance with U.S. Pat. No. 5,725,746. The device with rotating magnetron cathode, eliminating bearings degradation by the electric current, is described in US 2006/049043. WO 92/07105 discloses a fixing of interchangeable one-sided cylindrical rotation target, where the decomposition of a head of a cathode from the deposition chamber is not needed. A patent U.S. 5,445,721 discloses a structure of interchangeable, at both sides fixed cylindrical rotating magnetron. General structure of rotating cylindrical magnetron is described in publications U.S. 2008/0012460 or WO 91/07521.

Further, a method of using a cylindrical rotating magnetron with rotating magnetic field in combination with lateral cylindrical rotating magnetrons producing static magnetic field is known, as in a year 1984 a publication EP 0119631 discloses.

A method is known, where rotating magnetic field of permanent magnets is used, the field creating multiple electron ducts, and where a combination with static flat target is designed and so a yield of target material is ameliorated, as described in EP 1953257.

Designs of unbalanced magnetron with a flat target are known, where unbalanced magnetic field is created and outside magnetic field is much stronger than inside, or central magnetic field, as it is apparent from publication GB 2241710.

Further a design of unbalanced magnetron having flat target is known, where unbalanced magnetic field is used, as described in EP 1067577 or in W003/015475.

Designs of unbalanced magnetrons, where different shape of targets in each pair is used, are known, where the targets are arranged in such a way that magnetic field eliminates an escape of electrons outside of a deposition area and where plasma ionisation and quality of deposited layer are ameliorated. This type of magnetron is convenient for targets working in an operating mode where a power level is changing. This design is disclosed in U.S. 2002/0195336.

Further, the designs of unbalanced magnetrons with unbalanced magnetic field are known, where the working surface of target is placed inside or outside the target, as described in U.S. 2001/0050255.

Also modes of shaping magnetic fields of magnetron targets, using outside auxiliary magnetic pole pieces or outside magnetic fields, are known, as described in U.S. Pat. No. 6,749,730 and U.S. 2003/0089601.

Also using of rotating cylindrical shielding of cylindrical magnetron targets is known, as described for example in publications WO 94/16118 and EP 1251547.

### SUMMARY OF THE INVENTION

The purpose of the invention is to provide a new method and apparatus for depositing wear resistant layers, using in common a PVD method. The method of depositing wear resistant layer consists here in that depositing is carried out from at least two working deposition sources, simultaneously, where at least one of said sources is a cylindrical rotating cathode working in an unbalanced magnetron regime, and, simultaneously, at least one of said sources is a cathode, working in low-voltage arc-discharge regime.

The apparatus for carrying out this method consists of vacuum deposition chamber, in which there are at least two deposition sources with their relevant gas inputs of process gases and their shields, and in which at least one substrate on rotating support is placed, and where a nature of the invention is that at least one of said sources is a cylindrical rotating cathode working in an unbalanced magnetron regime, and simultaneously, at least one of said sources is a cathode, working in low-voltage arc-discharge regime. It is advantageous if the cylindrical rotating cathode, working in an unbalanced magnetron regime, is placed in the deposition chamber in a room inside a rotating support. In this case it is especially advantageous if the other working deposition sources are placed outside the rotating support. Alternatively it could be advantageous if both a cylindrical rotating cathode, working in unbalanced magnetron regime, and the other working deposition sources are placed in the deposition chamber outside the rotating support. Concerning an electric circuit connection, it is advantageous when the cylindrical rotating cathode working in unbalanced magnetron regime is shielded by a cylindrical shield, which is connected, in relation to said cathode, as an anode. Alternatively it could be advantageous if a cathode working in low-voltage arc-discharge regime is shielded by a cylindrical shield. In a version with the shield it is advantageous if said shield is equipped by a auxiliary gas input, respectively by just further auxiliary gas input of process gases.

In overall view, the nature of the invention consists in placing at least one, or more, of cylindrical rotating unbalanced magnetrons in proximity of a rotating support of deposition-covered substrates, said magnetron working with cooperation or with a possibility of cooperation with one or more working cathodes, where at least one of said cathodes works in a low-voltage arc-discharge regime.

Further, the nature of the invention consists in that said magnetron is equipped by a cylindrical shield, the construction of which could be various according to a purpose just needed, and by a rotating or swivelling magnetic field, which structural members could be combined in different positions or orientations of source surface of the magnetron cathode in relation to working cathodes and of construction or configuration of auxiliary gas inputs of process gases, where, in cooperation with shield modifications, a local changes of working gas atmosphere are possible.

Summary of advantages of the method and apparatus of the invention:
The cylindrical rotating magnetron provides a possibility of applying significantly higher power for magnetron discharge, comparing to low-voltage arc-discharge,
Significantly higher speed of growing a deposited layer, comparing to arc-discharge technology is achieved,
Significantly lower relative surface roughness, comparing to low-voltage arc is achieved,
Significantly higher level of ionisation, comparing to up-to-now magnetrons is achieved (ionisation level is deduced by counting a relation between a current to a substrate and a total number of ionized particles) and significantly higher speed of growing the layer (a number of “neutrals”), comparing up-to-now usual cylindrical rotating arc to the magnetron according to the invention,
When cooperating with arc-cathodes it is possible to achieve further supplementary ionization of plasma and of reaction components, involved in a layer creating process,
The working arc electrodes, in cooperation, are stabilizing hysteresis behaviour of the magnetron, said electrodes are suppressing a sensitivity of the magnetron in relation to changes of partial pressure of reactive components of working atmosphere and they are retarding a transition to a unstable working regime,
In combined configuration it is possible to use arc cathode for ion-cleaning, what provides significantly better adhesion of a deposited layer, comparing to using a sole magnetron for said ion-cleaning,
When using a magnetic field of the cylindrical rotating magnetron it is possible to achieve creating an unbalanced magnetron,
Magnetron duct or ducts of the cylindrical rotating magnetron could be oriented, in case of stationary field, towards the working electrodes or in a direction from those electrodes, and this way they could influence the structure of a deposited layer (in working regime with the orientation of magnetron ducts towards those electrodes, the materials of respective cathodes are going mixed and they dominantly create a monolayer, and in working regime with the orientation of magnetron ducts from those electrodes the materials of respective cathodes are not going mixed and so it is possible to create a multilayer structure, a thickness of which could be influenced or managed by process parameters),
When using further working electrodes in their cooperation it is, advantageously, possible to modify a composition and characteristics of a deposited PVD layer,
Cylindrical shield is preserving the cylindrical rotating magnetron from an influence of the other working cathodes, when depositing a material from those cathodes only,
It is possible to use the cylindrical shield for cleaning of the cylindrical rotating magnetron before a starting of deposition process when consequently shielding of substrates and suppressing this way an influence of residual particles released from the surface of target during the cleaning of the cylindrical rotating magnetron,
It is possible to use the cylindrical shield for starting process of the cylindrical rotating magnetron, for approaching to a working point, before starting a true deposition process, when consequently shielding the substrates from an influence of residual particles, released from surface of the target during this starting process,
It is possible to add, advantageously, a local, auxiliary input of gases, what enables to change locally a composition of working gas atmosphere.

It is possible to use the invention for modifying or adjusting some of known methods and apparatus, where only planar and no rotation or similar electrodes are used. Those apparatus, where a combining of planar electrodes, working on principle of a magnetron and of low-voltage arc-discharge, are known in general, but they are adjusted for performing a process either with one sort of electrode or with the other sort of electrode, but they are not adjusted for a process where both types of electrodes are working together, in cooperation. And when taking a basic nature and scope of the invention, a modifying a relevant apparatus for using planar electrodes is to be considered as a technical equivalent of the method and apparatus according to the invention.

### BRIEF DESCRIPTION OF THE DRAWINGS

The method and apparatus according to the invention is to be described in detail and explained using examples of the embodiments accompanied also by the relevant drawings, where, in simplified cross-sections, there is apparent on

FIG. 1 a deposition apparatus with a central magnetron and with working lateral, or side electrodes, placed outside a rotation substrate support, on

FIG. 2 there is, in detail, a cathode of cylindrical rotation magnetron, which cathode is created as a rotation cylindrical hollow target, with permanent magnets creating unbalanced magnetic field, on

FIG. 3 there is in detail the same electrode, where relevant magnetic field is drawn, being in a form of oval closed magnetic duct on the surface, the longer side of which is parallel to the axis of the target, on

FIG. 4 another variation of the method according the invention is illustrated, using an apparatus where a cylindrical rotational magnetron is placed inside a deposition chamber and inside a room of rotation support of substrates, together with another working cathode, working on principle of low-voltage arc-discharge, which another cathode is placed inside the room of rotation support, and, further, on

FIG. 5 another method according to the invention is illustrated, using an apparatus where a cylindrical rotation magnetron is placed inside the deposition chamber, but outside the rotation substrate support, and with another working cathode, working on principle low-voltage arc-discharge, on

FIG. 6, for illustrating a cleaning phase of the method, there is, in detail, a cathode of cylindrical rotation magnetron, the cathode is created as rotation cylindrical hollow target with permanent magnets, creating an unbalanced magnetic field, similar to the field on FIG. 2, but in this case the magnetic field of said cylindrical rotation magnetron being swivelled, what is caused by a position of ferromagnetic and swivelling core with permanent magnets from a working position, seen on FIG. 2, to a cleaning position, seen on this FIG. 6, and further on

FIG. 7 there is a deposition apparatus according to FIG. 1, where cleaning phase is in progress and this phase of the method can penetrate to a phase of ion etching using glow-discharge or arc-discharge from side cathodes, where at least one of those side cathodes is adjusted for working in low-voltage arc-discharge and so such a cathode is called arc cathode, and where in general, comparing to the apparatus on FIG. 1, a magnetic field of central rotation cylindrical magnetron is swivelled from a position as on FIG. 2 to a position as on FIG. 6, and, further, on

FIG. 8 there is the apparatus as on FIG. 1, but in a modified configuration, where side cathodes are shielded by their own cylindrical shielding, swivelled to a position closer to the central rotation magnetron, by which a deposition phase of TiAIN layer is illustrated, whereby only the central cylindrical rotation magnetron is used and the side cathodes are preserved by their own relevant cathode shields, and where a magnetic field of said magnetron is oriented towards the substrates outside the room behind the shield, and, finally,

FIG. 9 illustrates a deposition of TiAIN layer, carried out using a cooperation of the cylindrical rotation magnetron with a side cathode or cathodes, where at least one of them, called also arc cathode, is adjusted for acting in low-voltage arc-discharge working regime, when a magnetic field of this magnetron is oriented here towards the substrates outside the room behind the cylindrical shield and the orientation of the magnetron discharge is in direction from the side cathodes.

### DETAILED DESCRIPTION OF THE INVENTION

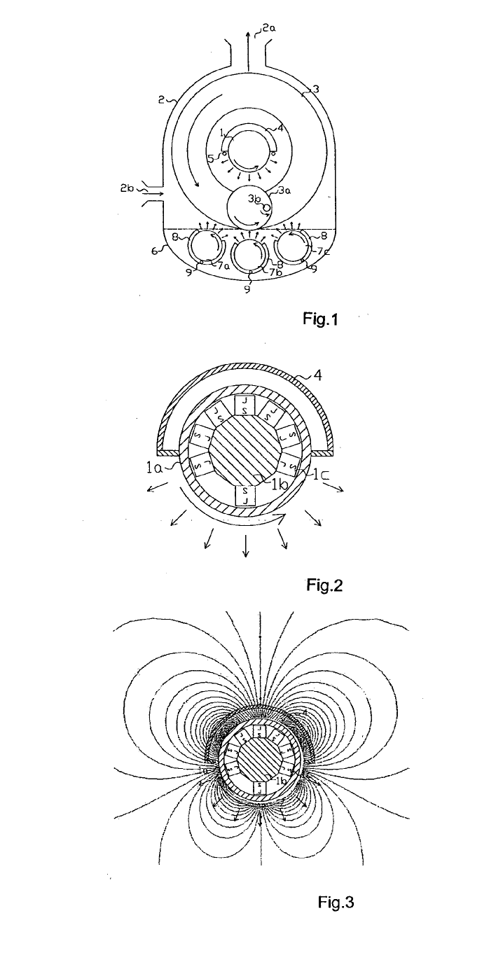

The method according to the invention is illustrated on the apparatus according to the invention, being an example embodiment of it and being based on known type Pi300, what is apparent on FIG. 1 and is created as follows.

The cylindrical rotation magnetron 1 is placed in a central position, inside a deposition chamber 2. The deposition chamber 2 consists of input 2b of process gases, output 2a for evacuation of gases, door 6 of the deposition chamber 2 and of rotation support 3 of substrates 3b. Rotation support 3 of substrates 3b provides a possibility to load the substrates 3b, ready to be coated, on the planets 3a and perform their multistage rotation. Coaxially to the cylindrical rotation magnetron 1 its cylindrical shield 4 is placed. In proximity of this cylindrical shield 4 it is possible to place an auxiliary gas input 5 or inputs of process gases. Outside the rotating support 3 of the substrates 3b in the area of the door 6 of the deposition chamber 2 working side cathodes 7a,7b,7c, including their relevant shield 8 of those working side cathodes and to them leaded further auxiliary gas input 9 or other process gas inputs, are placed. The sole construction of said working side cathodes and of their shields is known in the art and is described in detail in, for example, a publication EP 1356496. Any combination of using and placing respective types of working side cathodes 7a,7b,7c in this example embodiment is possible, but at least one of them is to be adjusted for being able to work in low-voltage arc-discharge regime.

On FIG. 2 a configuration is apparent, where a cathode of cylindrical rotation magnetron 1 consists of its own rotation cylindrical target 1a with a permanent magnets 1c, forming unbalanced magnetic field and being placed on a ferromagnetic and rotation core 1b inside the hollow room of said target 1a. Magnetic field in this example embodiment creates on a surface oval closed magnetic duct, the longer side of which is in a parallel position with an axis of said target 1a, as further is apparent on FIG. 3.

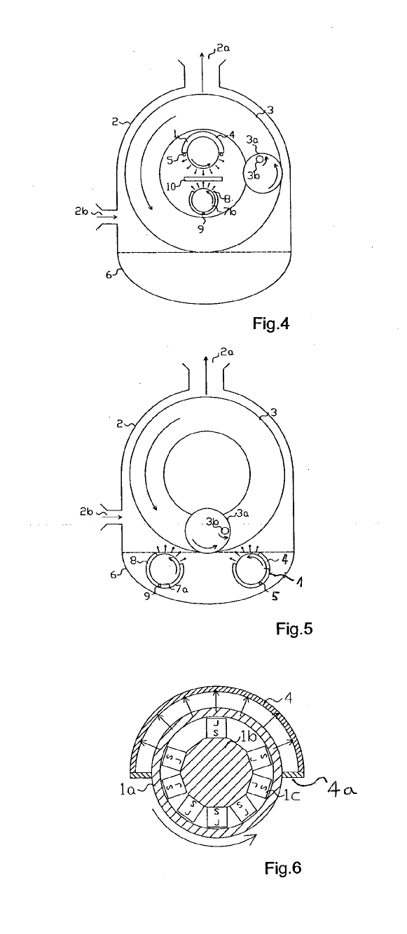

Another method according to the invention is illustrated on the apparatus according to the invention, in an example embodiment, which is apparent on FIG. 4 and is created as follows. Cylindrical rotation magnetron 1 is placed inside the deposition chamber 2 and inside a room of rotation support 3 of the substrates 3b, also with a further working cathode 7a, which is working on principle of low-voltage arc-discharge and which is situated inside a room of the rotation support 3. Deposition chamber 2 consists of an input 2b of process gases, output 2a for gas evacuation, door 6 of the deposition chamber 2 and a rotation support 3 of the substrates 3b. Rotation support 3 of the substrates 3b enables to load those substrates, intended to be coated, on respective planets 3a and enables their multistage rotation. Coaxially with the cylindrical rotation magnetron 1 its cylindrical shield 4 is situated. In a proximity of said cylindrical shield 4 it is possible to place the auxiliary gas inlet 5 or inlets of process gases. Working cathode 7a then uses a relevant shield 8 and a further auxiliary gas inlet 9 of further process gases, which inlet 9 leads in said shield 8.

Just another method according to the invention is illustrated by an apparatus according to the invention, in example embodiment, which is apparent on FIG. 5 and is created as follows. Cylindrical rotation magnetron 1 is situated inside the deposition chamber 2, outside the rotation support 3 of the substrates 3b with further working cathode 7a working on principle of low-voltage arc-discharge. The deposition chamber 2 consists here of the inlet 2b of process gases, outlet 2a for gases evacuation, door 6 of the deposition chamber 2 and the rotation support 3 of the substrates 3b. Rotation support 3 of the substrates 3b enables to load these substrates intended to be coated, on respective planets 3a and enables their multistage rotation. Coaxially with the cylindrical rotation magnetron 1 its cylindrical shield 4 is situated. In proximity of said cylindrical shield 4 it is possible to place the auxiliary gas inlet 5 or inlets of process gases. Working cathode 7a then uses a relevant shield 8 and a further auxiliary gas inlet 9 of further process gases, which inlet 9 leads in said shield 8.

Cylindrical shield 4 of the cylindrical rotation magnetron 1 can be designed in various forms, which are described in detail in following.
a) Stable shield, shielding approximately over an angle of 180° a surface of the target 1a. The shield 4a is galvanic separated from deposition chamber 2, using a connection on a floating potential, and is equipped by side adjustable parts 4a, which are adjustable according to making smaller the diameter of the target 1a. The cylindrical shield 4 can be oriented or positioned, in relation to side cathodes 7a,7b,7c, on the near or on the distant side.
b) Stable shield, shielding approximately over an angle of 180° a surface of the target 1a and creating an auxiliary anode. This type of a cylindrical shield 4 can be completed by water cooling system, according to an output power of cleaning. The form of this shield, in general, can be also different, not only having a form of simple round cylinder. This shield is equipped by side adjustable parts 4a, which are adjustable according to making the diameter of said target 1a smaller, consequently to its erosion. The cylindrical shield 4 can be, in this case, oriented on near or distant side.
c) Stable shield, according a design as in a) or b), completed by a rotating part, able to close fully said target 1a in the room of cylindrical shield 4. The cylindrical shield 4 can be, in this case, oriented on near or distant side.
d) Stable shield, completed inside or in a close proximity of said cylindrical shield 4, created otherwise as in a) or b) or c), by the auxiliary gas inlet 5 or gas inlets of process gases, enabling to change locally a composition of a process atmosphere.

Further the examples of the method according to the invention follow, where this method is carried out using the apparatus according to the invention in example embodiment, which is accompanied by further drawings, which are illustrating said method and apparatus.

### Example 1

### Deposition of TiAIN Layer, Using a Cooperation of Said Cylindrical Rotating Magnetron with Side Cathodes

A process of deposition of TiAIN layer, on coating apparatus Pi300 consists of following phases, using also generally known steps: evacuation of the deposition chamber, warming up tools to a working temperature, ion cleaning of the tools by a glow discharge or by an arc-discharge from side cathodes, cleaning of a cylindrical rotating magnetron, deposition of the layer using the cooperation of the cylindrical rotation magnetron with side cathode or cathodes, cooling the apparatus from the working, process temperature and, finally, aerating of the deposition chamber.

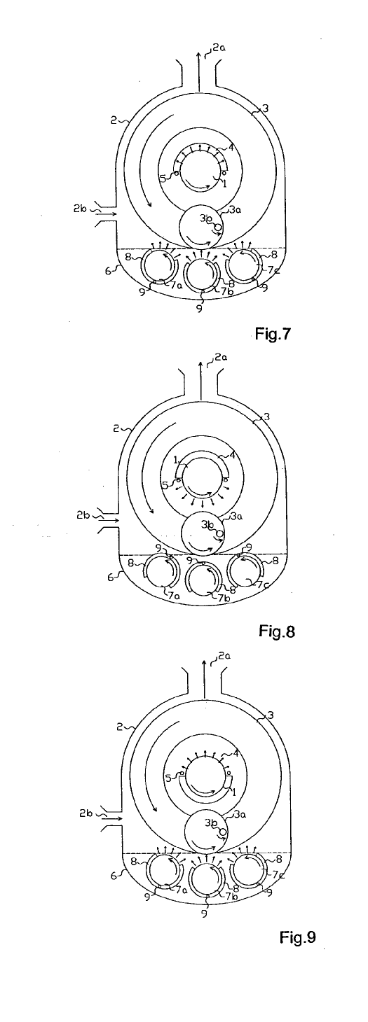

Following phases involve using the cylindrical rotation unbalanced magnetron and the side cathodes, according to the invention and according to the method, used for the apparatus, which is apparent on FIG. 1:
1. Cleaning the surface of the cylindrical rotation unbalanced magnetron 1 to the room behind the cylindrical shield 4, what is possible to see on FIG. 6. The surface of the cathode of said cylindrical rotation magnetron 1, created here in a form of rotating cylindrical hollow target 1a, can be contaminated for example by the oxygen and nitrogen from a preliminary aerating of the deposition chamber 2, or from a preliminary deposition process. The purpose of this phase is eliminating residual particles using a method suppressing or eliminating the deposition of residual particles released before and deposited on the surface of the substrates 3b, intended to be coated by relevant layer or layers. The cleaning phase begins by swivelling the magnetic field of said cylindrical rotation magnetron 1, according to a position of a ferromagnetic and swivelling core 1b with permanent magnets 1c, from a working position, as on FIG. 2, to a cleaning position, as on FIG. 6. The cylindrical shield 4 is connected here as an auxiliary anode. Process parameters of this phase are as follows: total pressure 0,4 Pa, only in Ar atmosphere, Ar flow 40 sccm, temperature 550° C., magnetron output power 6 kW, cleaning time 10 min. This phase can penetrate to a phase of ion etching of tools by a glow discharge or by an arc-discharge from the side cathodes 7a,7b,7c, as on FIG. 7. In this process at least one of those side cathodes 7a,7b,7c is adjusted for an activity in low-voltage arc-discharge working regime and so this cathode is called arc cathode in this case.
2. Deposition of adhesive layers from side cathodes 7a,7b,7c and from said cylindrical rotation magnetron 1, where during this phase a swivelling magnetic field of said cylindrical rotating magnetron 1 is used for orienting the discharge from the room behind the shield 4 to a direction towards the substrates 3b. Adhesive layers are deposited under a consequent activity, resp. under a cooperation of said cylindrical rotation magnetron 1 and the side cathodes 7a,7b,7c, in a configuration as on FIG. 1. For a local influencing of a composition of reaction atmosphere a local auxiliary gas input 5 is used, or a plurality of such gas inlets, and also further auxiliary gas inlet 9 or a plurality of such inlets are used, too. In this case a gradient transition of process parameters is used—total pressure regulated by nitrogen from 0,42 to 0,47 Pa, Ar flow 40 sccm, temperature 550° C., magnetron output power from 6 to 25 kW, arc cathode output power 150 A, voltage on samples from −120 to −75 V , deposition time 5 min.
3. Deposition of TiAIN layer, when using consequent activity or cooperation of said cylindrical rotation magnetron 1 and side cathodes or cathode 7a,7b,7c, where at least one of said cathodes is created as so called arc cathode, what means a cathode adjusted for working in low-voltage arc-discharge regime, as on FIG. 1. Magnetic field of said magnetron 1 is oriented towards the substrates 3b, outside the room behind the shield 4. During this TiAIN layer deposition process on the substrates 3b consequently a deposition process of particles released from the cathode of said cylindrical rotating magnetron 1 is carried out, and evaporating of a material of side cathode or cathodes 7a,7b,7c is carried out, too, under the low-voltage arc-discharge. For a local influencing of a composition of reaction atmosphere a local auxiliary gas input 5 is used in this case, too, or a plurality of such gas inlets is used, and also further auxiliary gas inlet 9 or a plurality of such inlets are used, too. In this case typical parameters of said deposition phase from said cylindrical rotation magnetron 1 are as follows—pressure from 0,3 to 0,8 Pa, Ar flow from 30 to 80 sccm, temperature from 300 to 600° C., magnetron output power from 5 to 30 kW, arc cathode output power 150 A, voltage on samples from −25 to −200 V , deposition time from 30 to 90 min.

### Example 2

### TiAIN Layer Deposition Using Only Said Cylindrical Rotation Magnetron

TiAIN layer deposition process on deposition or coating apparatus Pi300, consists in fact of following phases, using also generally known steps: evacuation of the deposition chamber, warming up tools to a working temperature, ion etching of the tools by a glow discharge or by an arc-discharge from side cathodes, cleaning of a cylindrical rotating magnetron to a room of shielding, deposition of the adhesive layers from side cathodes and from the cylindrical rotation magnetron, deposition of the main layer using only the cylindrical rotation magnetron activity, cooling the apparatus from the working, process temperature and, finally, aerating of the deposition chamber.

Following phases involve using the cylindrical rotation unbalanced magnetron according to the invention and according to the method, used for the apparatus, which is apparent on FIG. 1:
1. Cleaning of the cylindrical rotation magnetron 1 to the room behind the cylindrical shield 4. The surface of the cathode of said cylindrical rotation magnetron 1, which cathode is created here in a form of rotating cylindrical hollow target 1a, can be contaminated for example by the oxygen and nitrogen from a preliminary aerating of the deposition chamber 2. The purpose of this phase is eliminating residual particles using a method suppressing or eliminating the deposition of residual particles released before and deposited on the surface of the substrates 3b, intended to be coated by relevant layer or layers. The cleaning phase begins by swivelling the magnetic field of said cylindrical rotation magnetron 1, according to a position of a ferromagnetic and swivelling core 1b with permanent magnets 1c, from a working position, as on FIG. 2, to a cleaning position, as on FIG. 6. The cylindrical shield 4 is connected here as an auxiliary anode. Process parameters of this phase are as follows: total pressure 0,4 Pa, only in Ar atmosphere, Ar flow 40 sccm, temperature 550° C., magnetron output power 6 kW, cleaning time 10 min. This phase can penetrate to a phase of ion etching of tools by a glow discharge or by an arc-discharge from the side cathodes 7a,7b,7c, as on FIG. 7. In this process, too, at least one of those side cathodes 7a,7b,7c is adjusted for an activity in low-voltage arc-discharge working regime and so this cathode is called arc cathode in this case.
2. Deposition of adhesive layers from side cathodes 7a,7b,7c and from said cylindrical rotating magnetron 1, where during this phase a swivelling magnetic field is used for changing an orientation of the discharge from a room behind the cylindrical shield 4 to an orientation towards the substrates 3b, as on FIG. 7
3. Deposition of the main TiAIN layer, using only said cylindrical rotation magnetron 1, where side cathodes 7a,7b,7c are protected by their relevant shields 8 of said cathodes, as on FIG. 8. Magnetic field of said magnetron 1 is oriented towards the substrates 3b outside the room behind the shield 4, as on FIG. 2. Process parameters of said deposition phase are as follows—pressure from 0,3 to 0,8 Pa, Ar flow from 30 to 80 sccm, temperature from 300 to 600° C., magnetron output power from 5 to 30 kW, voltage on samples −75 V, deposition time from 30 to 120 min.

### Example 3

### Deposition by Discharges, Averted from Each Other

Deposition of the main TiAIN layer is carried out under cooperation of said cylindrical rotation magnetron 1 and said side cathode or cathodes 7a,7b,7c, where at least one of those cathodes, called arc cathode, is adjusted for acting in low-voltage arc-discharge working regime, what is to see be seen on FIG. 9. Magnetic field of said magnetron 1 is oriented towards the substrates 3b outside the room behind the cylindrical shield 4. Orientation of a magnetic discharge is in direction from the side cathodes 7a,7b,7c, as on FIG. 9, what enables a deposition process resulting in production of multilayer structure having a controlled thickness. In this configuration it is necessary to use a convenient material for the cylindrical rotation magnetron 1, which material do not cause a delaminating and cohesion failure inside said layer, built as a multilayer structure. For local influencing of a composition of reaction atmospheres here also the local auxiliary gas input 5, or a plurality of such inputs, is incorporated, and also the further auxiliary gas input 9, or a plurality of such inputs, is incorporated in said apparatus. Typical process parameters of said deposition phase, using said cylindrical rotation magnetron 1 are as follows: pressure from 0,3 to 0,8 Pa, Ar flow from 30 to 80 sccm, temperature from 300 to 600° C., magnetron output power from 5 to 30 kW, voltage on samples from −25 V to −200 V, deposition time from 30 to 90 min.

### Example 4

### TiAIN Layer Deposition, Using Said Cylindrical Rotation Magnetron and Low-voltage Arc-discharge

A deposition of the main TiAIN layer is carried out under cooperation of said cylindrical rotation magnetron 1 and said side cathode 7, where said cathode is adjusted for acting in low-voltage arc-discharge working regime, what is to be seen on FIG. 4. Magnetic field of said magnetron 1 is oriented in a direction towards the anode 10, where a combining of a mutual shielding of both cathodes is apparent, and said direction is outside the room behind the cylindrical shield 4. The orientation of a magnetron discharge is towards the other working cathode 7, as can be seen on FIG. 4, what enables the deposition of layers where a grade of material mixing among materials of respective cathodes is high. For local influencing of a composition of reaction atmospheres here also the local auxiliary gas input 5, or a plurality of such inputs, is incorporated, and also the further auxiliary gas input 9, or a plurality of such inputs, is incorporated in said apparatus. Typical process parameters of said deposition phase, using said cylindrical rotation magnetron 1 are as follows: pressure from 0,3 to 0,8 Pa, Ar flow from 30 to 80 sccm, temperature from 300 to 600° C., magnetron output power from 5 to 30 kW, current of arc cathode from 60 to 220 A, voltage on samples from −25 to −200 V, deposition time from 30 to 120 min.

Example 5

### TiAIN Layer Deposition, Using Said Cylindrical Rotation Magnetron and Low-voltage Arc-discharge, Where a Placing of Both Devices is Outside the Rotating Support of the Substrates

A deposition of the main TiAIN layer is carried out under cooperation of said cylindrical rotation magnetron 1 and said side cathode 7, where said cathode is adjusted for acting in low-voltage arc-discharge working regime, what is to be seen on FIG. 5. Magnetic field of said magnetron 1 is oriented in a direction towards the substrates 3b, and said direction is outside the room behind the cylindrical shield 4. The orientation of a magnetron discharge is towards the substrates 3b being the same as this orientation by the other working cathode 7, as can be seen on FIG. 5, what enables the deposition of layers where a grade of material mixing among materials of respective cathodes is high. For local influencing of a composition of reaction atmospheres here also the local auxiliary gas input 5, or a plurality of such inputs, is incorporated, and also the further auxiliary gas input 9, or a plurality of such inputs, is incorporated in said apparatus. Typical process parameters of said deposition phase, using said cylindrical rotation magnetron 1 are as follows: pressure from 0,3 to 0,8 Pa, Ar flow from 30 to 80 sccm, temperature from 300 to 600° C., magnetron output power from 5 to 30 kW, current of arc cathode from 60 to 220 A, voltage on samples from −25 to −200 V, deposition time from 30 to 120 min.

### INDUSTRIAL APPLICABILITY

The method and the apparatus according to the invention are convenient for being used for deposition of layers or coatings, especially for coating a substrate by wear resistant layers, where especially even and regular layer with reduced number of macroparticles and a broad variability by a deposition process is needed.

1. A method of depositing wear resistant layers, using PVD method, characterized in that the depositing is carried out from at least two working deposition sources, simultaneously, where at least one of said sources is a cylindrical rotating cathode working in an unbalanced magnetron (1) regime, and, simultaneously, at least one of said sources is a cathode (7a,7b,7c), working in low-voltage arc-discharge regime.

2. The apparatus for carrying out the method according to claim 1, consisting of vacuum deposition chamber, in which there are at least two deposition sources with their relevant gas inputs of process gases and their shields, and in which at least one substrate on rotating support is placed, characterized in that at least one of said sources is a cylindrical rotating cathode working in an unbalanced magnetron regime, and, simultaneously, at least one of said sources is a cathode (7a,7b,7c), working in low-voltage arc-discharge regime.

3. The apparatus according to claim 2 characterized in that the cylindrical rotating cathode, working in an unbalanced magnetron regime, is placed in the deposition chamber (2) in a room inside a rotating support (3).

4. The apparatus according to claim 3 characterized in that the other working deposition sources are placed outside the rotating support (3).

5. The apparatus according to claim 2 characterized in that both a cylindrical rotating cathode, working in unbalanced magnetron regime, and the other working deposition sources are placed in the deposition chamber (2) outside the rotating support (3).

6. The apparatus according to claim 2 characterized in that the cylindrical rotating cathode working in unbalanced magnetron regime is shielded by a cylindrical shield (4), which is connected, in relation to said cathode, as an anode.

7. The apparatus according to claim 2 characterized in that the cathode (7a,7b,7c) working in low-voltage arc-discharge regime is shielded by a cylindrical shield (8).

8. The apparatus according to claim 6 characterized in that the shield (4,8) is equipped by a auxiliary gas input (5), respectively by just further auxiliary gas input (9) of process gases.
